(19) United States
(12) Patent Application Publication
(10) Pub. No.: US 2024/0004262 A1
(43) Pub. Date: Jan. 4, 2024

(54) TANTALA-RING-RESONATOR-BASED PHOTONIC DEVICE AND FREQUENCY-COMB GENERATION METHOD

(71) Applicants: The Regents of the University of Colorado, a body corporate, Denver, CA (US); Government of the United States of America, as Represented by the Secretary of Commerce, Gaithersburg, MD (US)

(72) Inventors: Su-Peng Yu, Boulder, CO (US); Scott B. Papp, Boulder, CO (US); David Carlson, Boulder, CO (US); Kartik Srinivasan, Rockville, MD (US); Hojoong Jung, Seoul (KR)

(21) Appl. No.: 18/368,886

(22) Filed: Sep. 15, 2023

Related U.S. Application Data
(63) Continuation of application No. 16/501,134, filed on Jul. 10, 2020, now abandoned.
(60) Provisional application No. 62/872,402, filed on Jul. 10, 2019.

(51) Int. Cl. G02F 1/35; G02F 1/355; C23C 14/34; C23C 14/58; G03F 7/20; C23C 14/08; C23C 14/46

(52) U.S. Cl. CPC G02F 1/3513; G02F 1/355; C23C 14/34; C23C 14/5826; C23C 14/5806; G03F 7/2037; C23C 14/083; C23C 14/46; G02F 2203/17

(57) ABSTRACT

A photonic device includes a substrate and a tantala ring resonator on the substrate. The tantala ring resonator has at least one of (i) a quality factor exceeding three million and (ii) a threshold power less than one hundred milliwatts. A frequency-comb generation method includes sweeping the output frequency of a laser coupled to a tantala ring resonator that has at least one of (i) a quality factor exceeding three million and (ii) a threshold power less than one hundred milliwatts.

### CROSS-REFERENCE TO RELATED APPLICATIONS

This application is a continuation of U.S. patent application Ser. No. 16/501,134, filed on 10 Jul. 2020, which claims priority to U.S. Provisional Patent Application No. 62/872,402, filed on 10 Jul. 2019. Each of these applications is incorporated herein by reference in its entirety.

### GOVERNMENT RIGHTS

This invention was made with government support under grant number 70NANB18H006 awarded by NIST. The government has certain rights in the invention.

### BACKGROUND

Integrated photonics that enable nonlinear optical processes are important for numerous applications, including precision metrology, microscopy, micro-resonator frequency comb generation; optical signal generation and processing; sensing, positioning, and navigation; and generation and manipulation of quantum information. Nonlinear optical photonics may be fabricated using silicon nitride (Si₃N₄), which has acceptable Kerr nonlinear coefficient and low optical loss.

### SUMMARY

Integrated nonlinear photonics utilizing tantalum pentoxide (tantala) is disclosed, offering important advantages compared to the existing state of practice in nonlinear photonics. The described ring resonator and method of fabrication enables high-performance nonlinear photonics devices (e.g. micro-resonator frequency combs) to be created at lower cost and higher yield than existing technologies.

Also disclosed is the use of tantala material with properties supporting nonlinear processes like micro-resonator frequency comb generation and supercontinuum generation. Semiconductor processing techniques facilitate depositing tantala material on thermally oxidized silicon wafers and fabricated integrated nonlinear photonics devices, as disclosed herein.

Fabricating integrated nonlinear photonics with tantala takes advantage of the superior properties of this material, which may include deposition, lithography, chemical etching, and thermal processing approaches to realize integrated nonlinear photonics devices. The described method of fabrication of nonlinear photonics advantageously exploits the superior properties of tantala, namely low tensile stress that enables high-yield fabrication, and high optical quality factor which leads to low optical losses, allowing efficient excitation of nonlinear processes. Low thermal processing temperature maintains process compatibility for co-integration with other photonics materials and semiconductor processes.

Tantala solves certain problems in nanofabrication, compared to other materials like silicon nitride that represent the current state-of-practice. Therefore, tantala is an important material platform that offers higher yield of devices designed for integrated nonlinear photonics. Key properties that make tantala attractive for nonlinear photonics include wide optical transparency window, low tensile stress for high yield in nanofabrication, and relatively low thermal processing temperature to maintain compatibility for co-integration with other integrated photonics materials. When using the method of fabrication described herein, tantala photonic devices have low optical losses to enable efficient nonlinear photonics processes.

Integrated nonlinear photonics are important in the areas of precision metrology and sensing, nonlinear science, high-speed data communications, wideband signal analysis and generation, and for quantum information science.

In a first aspect, a photonic device includes a substrate and a tantala ring resonator on the substrate. The tantala ring resonator has at least one of (i) a quality factor exceeding three million and (ii) a threshold power less than one hundred milliwatts. In a second aspect, a frequency-comb generation method includes sweeping the output frequency of a laser coupled to a tantala ring resonator of the first aspect.

In a second aspect, a frequency-comb generation method includes sweeping the output frequency of a laser coupled to a tantala ring resonator that has at least one of (i) a quality factor exceeding three million and (ii) a threshold power less than one hundred milliwatts.

### BRIEF DESCRIPTION OF THE FIGURES

FIG. 1A and FIG. 1B illustrate a side view and a top view, respectively, of a photonic device with a tantala ring resonator, according to an embodiment.

FIG. 2 is a flowchart that illustrates a method for fabricating tantala nonlinear photonics, according to an embodiment.

### DETAILED DESCRIPTION

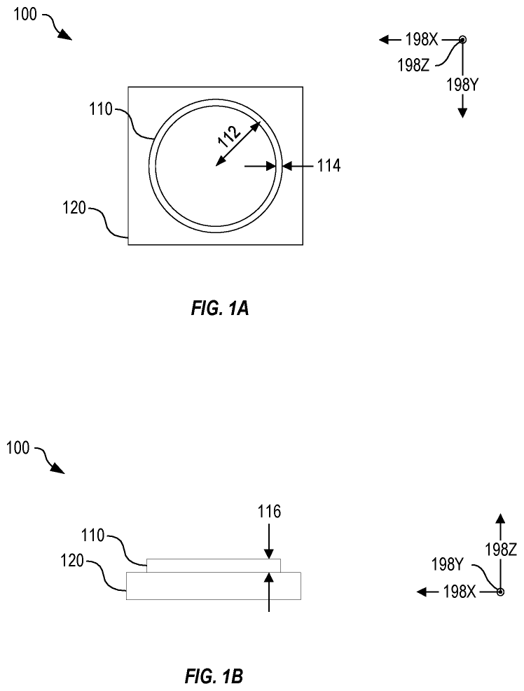

FIG. 1A and FIG. 1B illustrate a side view and top view, respectively, of a photonic device 100 with a tantala ring resonator 110 and a substrate 120. FIG. 1A and FIG. 1B are best viewed together. The top view illustrated in FIG. 1A is parallel to a plane, hereinafter the x-y plane, formed by orthogonal axes 198X and 198Y, which are each orthogonal to an axis 198Z. Planes parallel to the x-y plane are referred to as horizontal planes. The side view illustrated in FIG. 1B is parallel to a plane hereinafter the x-z plane, formed by orthogonal axes 198X and 198Z. Unless otherwise specified, heights of objects herein refer to the object's extent along axis 298Z. Herein, a reference to an axis x, y, or z refers to axes 198X, 198Y, and 198Z respectively. Also, herein, a width refers to an object's extent along the y axis, and vertical refers to a direction along the z axis. Also, herein, above refers to a relative position a distance away along the axis 298Z in the positive direction and below refers to a relative position a distance away along the axis 298Z in the negative direction.

The tantala ring resonator 110 is formed by depositing tantala using an ion-beam sputtering technique, which leads to formation of the tantala ring resonator 110 with high optical quality factor. In an embodiment, the ring resonator 110 has an optical quality factor larger than 3.8×10⁶.

The tantala ring resonator 110 has a radius 112 and a ring thickness 114. In an embodiment, the radius 112 is 46 micrometers and the ring thickness 114 is 1.5 micrometers. The ring radius 112 and the ring thickness 114 may each be either larger or smaller without departing from the scope hereof. The tantala ring resonator 110 has a height 116, which may be between 500 nanometers and 1000 nanometers. In an embodiment, the height is 800 nm.

The substrate 120 may be a semiconductor such as silicon. In an embodiment, the substrate 120 made from a silicon wafer that is thermally oxidized.

The tantala ring resonator 110 formed using ion-beam sputtering can be used for Kerr nonlinear process due to the high optical quality factor that results from using ion-beam sputtering fabrication. The low-loss associated with the tantala ring resonator 110 formed in this way allows its use in ultra-broadband Kerr-soliton frequency combs. Tantala nonlinear optics formed using prior fabrication processes have lower optical quality factors, which leads to loss of optical power during use. As a result, prior art tantala nonlinear optics require larger input optical power, which makes their use in frequency combs frustrated. The low losses associated with the tantala ring resonator 110 fabricated with ion-beam sputtering make it possible for use in ultra-broadband Kerr-soliton frequency combs.

Similar power requirements and optical quality factor arguments are relevant for use of the tantala ring resonator 110 in supercontinuum generation across the near-infrared spectral range of light. Because of the high optical quality factor, less input optical power is required to initiate supercontinuum generation, making devices such as photonic device 100 amenable to a range of supercontinuum applications not available to other tantala nonlinear photonic devices that are formed using prior art fabrication methods. The high losses associated with these prior art device increases the required input power for supercontinuum generation unfavorably.

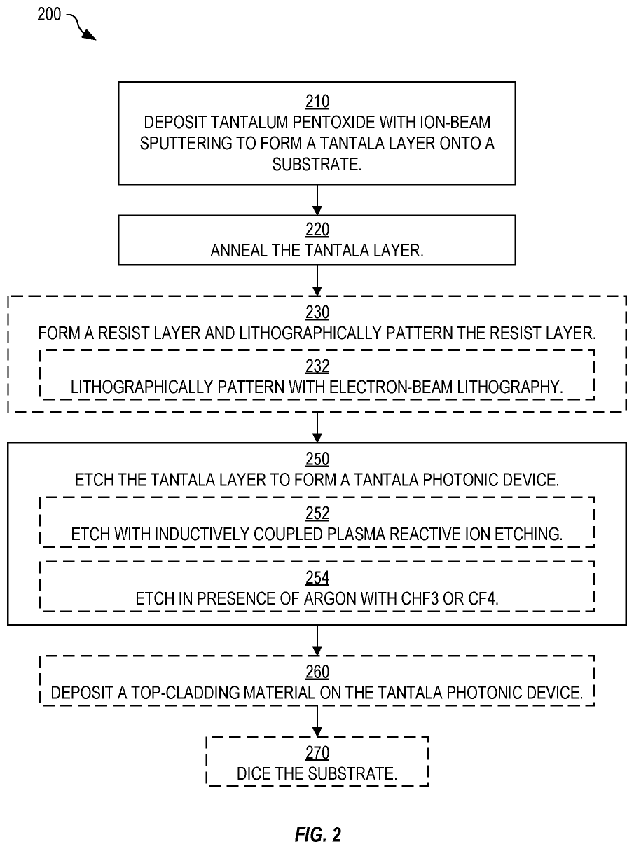

FIG. 2 is a flowchart illustrating a method 200 for fabricating nonlinear photonic devices. The method 200 may be used to generate the tantala ring resonator 110 of the photonic device 100. The method 200 includes at least blocks 210, 220 and 250 and in embodiments includes blocks 230, 232, 252, 254, 260 and 270.

In block 210, tantalum pentoxide is deposited with ion-beam sputtering to form a tantala layer on a substrate. The substrate is formed of at least one material selected from the group consisting of silicon, thermally oxidized silicon, sapphire, single crystal quartz, fused silica, gallium arsenide, aluminum gallium arsenide, gallium phosphide, and lithium niobate. The tantala layer may be 570 nanometers or 820 nanometers thick (measured along the z-axis in FIG. 1), though the tantala layer may be thinner or thicker without departing from the scope hereof. The thickness may be chosen to satisfy phase-matching conditions for light that may be introduced into the nonlinear photonic device. In an embodiment, the nonlinear photonic device is a ring resonator and the thickness is chosen to satisfy the phase-matching condition of light inside the ring resonator. In one example, the tantala layer is 570 nanometers thick and has a top air-cladded configuration. In one example, the tantala layer is 820 nanometers thick and uses a silica-cladded configuration. Forming the tantala layer using ion-beam sputtering contributes to the higher optical quality factor exhibited by tantala photonic devices fabricated using method 200 compared to devices fabricated using other methods.

In block 220, the tantala layer is annealed. In an embodiment, the tantala layer is annealed at 600° C. for 5 hours with oxygen background gas. The annealing temperature may be higher or lower and annealing time may be longer or shorter without departing from the scope hereof. For example, the annealing temperature may be between 400° C. and 700° C., and the annealing time may be between one hour and twelve hours. In an embodiment, the annealing is done with nitrogen background gas. Annealing the tantala contributes to the high optical quality factor exhibited by tantala photonic devices fabricated using method 200. In an embodiment, block 220 includes annealing the tantala layer in the presence of a gas mixture consisting of oxygen gas and nitrogen gas.

In block 250, the tantala layer is etched to form a tantala photonic device. In an embodiment, the tantala photonic device is a ring resonator, such as tantala ring resonator 110. Other tantala photonic devices with high optical quality factor may be fabricated using method 200 without departing from the scope hereof.

In certain embodiments, the method 200 includes one or more additional blocks of the flowchart in FIG. 2. In block 230, a resist layer is formed that is lithographically patterned. In block 232, the resist layer is lithographically patterned with electron-beam lithography. In an embodiment, the resist layer is positive tone and formed of ZEP-520A.

In block 252, the tantala layer is etched using inductively coupled plasma reactive ion etching and in block 254, the etching is done in the presence of argon and one or both of CHF₃ or CF₄. In an embodiment, the tantala photonic device and the substrate are cleaned to remove any residual organic material using a sulfuric-acid based oxidizer. In an embodiment, the fluoropolymer residue from the plasma process is removed from the tantala photonic device and the substrate.

In block 260, a top-cladding material is deposited on the tantala photonic device, including any exposed areas on the top and the sides. The top-cladding material formed from a material chosen from a group consisting of thermally oxidized silicon, sapphire, single crystal quartz, and fused silica. The top-cladding material may be deposited using inductively coupled plasma chemical vapor deposition, though other deposition methods may be used. The top-cladding may be selected to optimize the phase matching requirements of the intended use of the nonlinear photonic device.

In block 270, the substrate is diced. This may be done to isolate the portion of the substrate to which the tantala photonic device is attached and separate it from a remaining portion of the substrate. In an embodiment, the blocks of method 200 may be applied to multiple locations of the substrate and each may be diced to generate a plurality of individual nonlinear photonic devices, each with a portion of substrate and a tantala photonic device. In an embodiment, the dicing is done using a combination of ultra violet laser lithography and silicon deep reactive-ion etching, though other dicing method may be used.

Changes may be made in the above methods and systems without departing from the scope hereof. It should thus be noted that the matter contained in the above description or shown in the accompanying drawings should be interpreted as illustrative and not in a limiting sense. The following claims are intended to cover all generic and specific features described herein, as well as all statements of the scope of the present method and system, which, as a matter of language, might be said to fall therebetween.

What is claimed is:

1. A photonic device, comprising:
a substrate; and
a tantala ring resonator formed on the substrate and having at least one of (i) an internal quality factor exceeding three million and (ii) a threshold power for parametric oscillation that is less than 100 mW.

2. The photonic device of claim 1, the internal quality factor exceeding three million.

3. The photonic device of claim 1, the threshold power for parametric oscillation being less than 100 milliwatts.

4. The photonic device of claim 1, the internal quality factor exceeding three million and the threshold power for parametric oscillation being less than 100 milliwatts.

5. The photonic device of claim 1, the threshold power for parametric oscillation being less than 40 mW.

6. The photonic device of claim 1, the substrate being formed of at least one material selected from the group consisting of silicon, thermally oxidized silicon, sapphire, single-crystal quartz, fused silica, gallium arsenide, aluminum gallium arsenide, gallium phosphide, and lithium niobate.

7. The photonic device of claim 1, the tantala ring resonator having a thickness between 500 nm and 1000 nm.

8. The photonic device of claim 1, further comprising a top cladding disposed on the tantala ring resonator.

9. The photonic device of claim 8, the top cladding being formed of at least one material selected from the group consisting of thermally oxidized silicon, sapphire, single-crystal quartz, and fused silica.

10. A frequency-comb generation method, comprising:
sweeping the frequency of a laser having a laser output that is coupled into a tantala ring resonator, the tantala ring resonator having at least one of (i) an internal quality factor exceeding three million and (ii) a threshold power for parametric oscillation that is less than 100 mW.

11. The frequency-comb generation method of claim 10, the internal quality factor exceeding three million.

12. The frequency-comb generation method of claim 10, the threshold power for parametric oscillation being less than 100 mW.

13. The frequency-comb generation method of claim 10, the internal quality factor exceeding three million and the threshold power for parametric oscillation being less than 100 mW.

14. The frequency-comb generation method of claim 10, the laser output having a power less than 100 mW.

15. The frequency-comb generation method of claim 10, the threshold power for parametric oscillation being less than 40 mW.

16. The frequency-comb generation method of claim 10, the laser output having a power less than 40 mW.

17. The frequency-comb generation method of claim 10, further comprising coupling the laser output into the tantala ring resonator.

18. The frequency-comb generation method of claim 10, further comprising coupling a Kerr soliton frequency comb out of the tantala ring resonator.
